(19) United States
(12) Patent Application Publication
(10) Pub. No.: US 2015/0380500 A1
(43) Pub. Date: Dec. 31, 2015

(54) Ga2O3-BASED SINGLE CRYSTAL SUBSTRATE

(71) Applicants: TAMURA CORPORATION, Tokyo (JP); KOHA CO., LTD., Tokyo (JP)

(72) Inventors: Takekazu MASUI, Tokyo (JP); Kimiyoshi KOSHI, Tokyo (JP); Kei DOIOKA, Tokyo (JP); Yu YAMAOKA, Tokyo (JP)

(21) Appl. No.: 14/634,383

(22) Filed: Feb. 27, 2015

(30) Foreign Application Priority Data
Jun. 30, 2014 (JP) 2014-135455

(51) Int. Cl. H01L 29/24; C01G 15/00; C30B 29/16; H01L 29/04

(52) U.S. Cl. CPC H01L 29/24; H01L 29/04; C01G 15/00; C30B 29/16

(57) ABSTRACT

A Ga₂O₃-based single crystal substrate includes a main surface including BOW of not less than −13 μm and not more than 0 μm. The main surface may further include WARP of not more than 25 μm. The main surface may further include TTV of not more than 10 μm.

The present application is based on Japanese patent application No. 2014-135455 filed on Jun. 30, 2014, the entire contents of which are incorporated herein by reference.

### BACKGROUND OF THE INVENTION

1. Field of the Invention

The invention relates to a Ga₂O₃-based single crystal substrate.

2. Description of the Related Art

A method of manufacturing a gallium oxide single crystal substrate is known in which a (100) plane of a gallium oxide single crystal is ground (see e.g., JP-A-2008-105883).

JP-A-2008-105883 discloses a method by which it is possible to form steps and terraces on the (100) plane of the gallium oxide single crystal by a lapping process on the (100) plane so as to thin the gallium oxide single crystal, a polishing process thereon so as to smoothen the plane and then a chemical mechanical polishing thereon.

On the other hand, a method is known which allows the manufacture of a gallium oxide substrate without chipping, cracking, peeling etc. (see e.g., JP-A-2013-067524).

JP-A-2013-067524 discloses the method that a first orientation flat is formed at a peripheral edge of a main surface within an error of ±5° of rotational angle about a normal line passing through the central point of the main surface, the first orientation flat intersecting with the (100) plane at an angle of 90±5° and intersecting with the main surface as a plane other than the (100) plane at an angle of 90±5°, a second orientation flat is further formed at another position of the peripheral edge of the main surface so as to be point-symmetrically arranged with the first orientation flat where the central point of the main surface of the gallium oxide substrate is a symmetry point, and then, the gallium oxide substrate is manufactured by cutting the gallium oxide single crystal into a circular shape with the first and second orientation flats remained so that OL falls within a range of not less than 0.003×WD and not more than 0.067×WD, where the WD is defined as a diameter of the gallium oxide substrate and the OL is defined as a depth in diameter direction of the first and second orientation flats, thereby preventing the chipping, cracking, peeling etc.

### SUMMARY OF THE INVENTION

Semiconductor substrates or semiconductor support substrates which are currently used for manufacturing a semiconductor device include Si substrates (cubic system, diamond structure), GaAs substrates (cubic system, zinc blende structure), SiC substrates (cubic system, hexagonal system), GaN substrates (hexagonal system, wurtzite structure), ZnO substrates (hexagonal system, wurtzite structure) and sapphire substrates (rhombohedral crystal to be precise but generally approximately expressed as hexagonal system) etc. which are crystal systems with good symmetry. Gallium oxide substrates, however, belong to the monoclinic system which is a crystal system with poor symmetry and has very high cleavability. Thus, it was unknown even whether or not it is possible to stably produce gallium oxide substrates with an excellent shape. It is therefore considered that, when a Ga₂O₃ single crystal substrate is cut out so as to have a diameter of 2 inches, height of the center of the substrate from a reference plane (BOW), the sum of the absolute values of distances of the highest and lowest points from the reference plane of the substrate (WARP) or thickness variation in the substrate with respect to the flattened back surface of the substrate (TTV) could be more than a predetermined value.

The methods of manufacturing gallium oxide substrate disclosed in JP-A-2008-105883 and JP-A-2013-067524 fail to disclose how to manufacture the substrates of not less than 2 inches which is the size for commercial use.

It is an object of one embodiment of the invention to provide a Ga₂O₃-based single crystal substrate with an excellent shape reproducibility and stability.

According to one embodiment of the invention, a Ga₂O₃-based single crystal substrate as set forth in [1] to [6] below is provided.
[1] A Ga₂O₃-based single crystal substrate, wherein BOW of a main surface is not less than −13 μm and not more than 0 μm.
[2] The Ga₂O₃-based single crystal substrate according to [1], wherein WARP of the main surface is not more than 25 μm.
[3] The Ga₂O₃-based single crystal substrate according to [1] or [2], wherein TTV of the main surface is not more than 10 p.m.
[4] The Ga₂O₃-based single crystal substrate according to any one of [1] to [3], wherein the main surface has an average roughness Ra of 0.05 nm to 1 nm.
[5] The Ga₂O₃-based single crystal substrate according to [4], wherein a surface opposite to the main surface has an average roughness Ra of not less than 0.1 μm.
[6] The Ga₂O₃-based single crystal substrate according to any one of [1] to [5], comprising Sn added in an amount of 0.003 to 1.0 mol %.

### Effects of the Invention

According to one embodiment of the invention, a Ga₂O₃-based single crystal substrate with an excellent shape reproducibility and stability can be provided.

### BRIEF DESCRIPTION OF THE DRAWINGS

Next, the present invention will be explained in more detail in conjunction with appended drawings, wherein:

FIG. 1 is a vertical cross-sectional view showing a part of an EFG crystal manufacturing apparatus in an embodiment;

FIG. 2 is a perspective view showing a state during growth of a β-Ga₂O₃-based single crystal;

FIG. 3 is an illustration diagram showing three reference points R1, R2 and R3 for defining a three point preference plane of a β-Ga₂O₃-based single crystal substrate;

FIG. 4 is an illustration diagram showing measurement criteria for BOW of the β-Ga₂O₃-based single crystal substrate;

FIG. 5 is an illustration diagram showing measurement criteria for WARP of the β-Ga₂O₃-based single crystal substrate;

FIG. 6 is an illustration diagram showing measurement criteria for TTV of the β-Ga₂O₃-based single crystal substrate;

FIG. 7 is an illustration diagram showing a relation between BOW, WARP and the shape of the substrate;

FIG. 8 is a graph showing full width at half maximum (FWHM) of x-ray diffraction rocking curve from the β-Ga₂O₃-based single crystal substrate in the embodiment of the present invention;

FIG. 9 is an illustration diagram showing a process of manufacturing a β-Ga₂O₃-based single crystal substrate from a β-Ga₂O₃-based single crystal; and

FIG. 10 is an illustration diagram showing the β-Ga₂O₃-based single crystal substrate in the embodiment of the invention.

### DETAILED DESCRIPTION OF THE PREFERRED EMBODIMENTS

### Embodiment

In the present embodiment, a plate-shaped β-Ga₂O₃-based single crystal doped with Sn is grown from a seed crystal in a b- or c-axis direction. It is thereby possible to obtain a β-Ga₂O₃-based single crystal with small crystal quality variation in a direction perpendicular to the b- or c-axis direction.

Conventionally, Si is often used as a conductive impurity to be doped into a Ga₂O₃ crystal. Among conductive impurities doped into the Ga₂O₃ crystal, Si has a relatively low vapor pressure at a growth temperature of a Ga₂O₃ single crystal and there is less evaporation during crystal growth. Therefore, conductivity of the Ga₂O₃ crystal is relatively easily controlled by adjusting an amount of Si to be added.

On the other hand, as compared to Si, Sn has higher vapor pressure at a growth temperature of a Ga₂O₃ single crystal and there is more evaporation during crystal growth. Therefore, it is somewhat difficult to handle Sn as a conductive impurity to be doped into the Ga₂O₃ crystal.

However, concerning addition of Si, the inventors of the present invention found a problem that, under a specific condition such as growing a plate-shaped β-Ga₂O₃-based single crystal in a b- or c-axis direction, the crystal structure is uniform in the b- or c-axis direction but varies greatly in a direction perpendicular to the b- or c-axis direction. Then, the inventors of the present invention found that this problem is solved by adding Sn instead of Si.

(Growth of β-Ga₂O₃-Based Single Crystal)

A method using EFG (Edge-defined film-fed growth) technique will be described below as an example method of growing a plate-shaped β-Ga₂O₃-based single crystal. However, the growth method of a plate-shaped β-Ga₂O₃-based single crystal in the present embodiment is not limited to the EFG method and may be another growth method, e.g., a pulling-down method such as micro-PD (pulling-down) method. Alternatively, a plate-shaped β-Ga₂O₃-based single crystal may be grown by the Bridgman method combined with a die having a slit as is a die used in the EFG method.

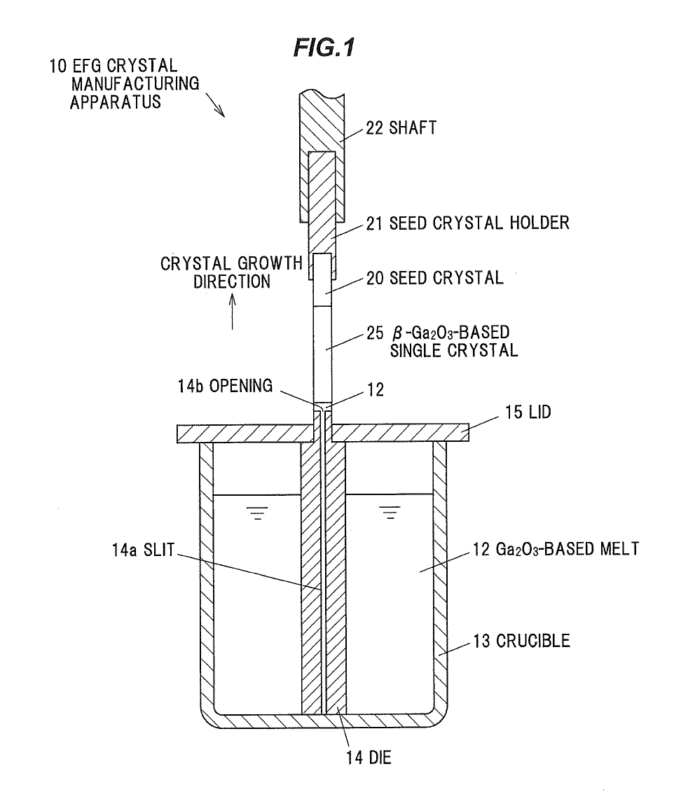

FIG. 1 is a vertical cross-sectional view showing a part of an EFG crystal manufacturing apparatus in the present embodiment. An EFG crystal manufacturing apparatus 10 has a crucible 13 containing Ga₂O₃-based melt 12, a die 14 placed in the crucible 13 and having a slit 14a, a lid 15 covering the upper surface of the crucible 13 so that the upper portion of the die 14 including an opening 14b of the slit 14a is exposed, a seed crystal holder 21 for holding a β-Ga₂O₃-based seed crystal (hereinafter, referred as “seed crystal”) 20, and a shaft 22 vertically movably supporting the seed crystal holder 21.

The crucible 13 contains the Ga₂O₃-based melt 12 which is obtained by melting Ga₂O₃-based powder. The crucible 13 is formed of a heat-resistant material such as iridium capable of containing the Ga₂O₃-based melt 12.

The die 14 has the slit 14a to draw up the Ga₂O₃-based melt 12 by capillary action.

The lid 15 prevents the high-temperature Ga₂O₃-based melt 12 from evaporating from the crucible 13 and further prevents the vapor of the Ga₂O₃-based melt 12 from attaching to a portion other than the upper surface of the slit 14a.

The seed crystal 20 is moved down and is brought into contact with the Ga₂O₃-based melt 12 which is drawn up to the opening 14b of the slit 14a by capillary action. Then, the seed crystal 20 in contact with the Ga₂O₃-based melt 12 is pulled up, thereby growing a plate-shaped β-Ga₂O₃-based single crystal 25. The crystal orientation of the β-Ga₂O₃-based single crystal 25 is the same as the crystal orientation of the seed crystal 20 and, for example, a plane orientation and an angle in a horizontal plane of the bottom surface of the seed crystal 20 are adjusted to control the crystal orientation of the β-Ga₂O₃-based single crystal 25.

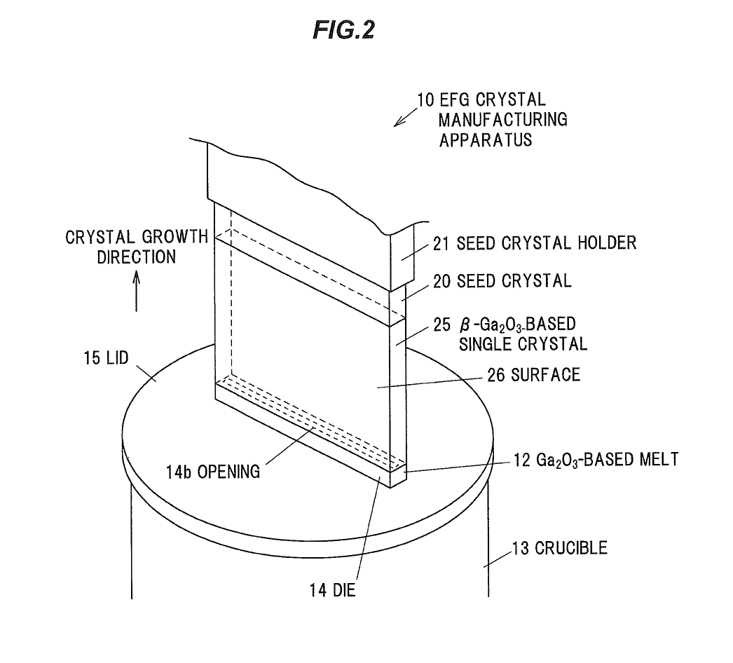

FIG. 2 is a perspective view showing a state during growth of a β-Ga₂O₃-based single crystal. A surface 26 in FIG. 2 is a main surface of the β-Ga₂O₃-based single crystal 25 which is parallel to a slit direction of the slit 14a. When a β-Ga₂O₃-based substrate is formed by cutting out from the grown β-Ga₂O₃-based single crystal 25, the plane orientation of the surface 26 of the β-Ga₂O₃-based single crystal 25 is made to coincide with the desired plane orientation of the main surface of the β-Ga₂O₃-based substrate. When forming a β-Ga₂O₃-based substrate of which main surface is, e.g., a (−201) plane, the plane orientation of the surface 26 is (−201). The grown β-Ga₂O₃-based single crystal 25 also can be used as a seed crystal for growing a new β-Ga₂O₃-based single crystal. The crystal growth direction shown in FIGS. 1 and 2 is a direction parallel to the b-axis of the β-Ga₂O₃-based single crystal 25 (the b-axis direction). The main surface of the β-Ga₂O₃-based substrate is not limited to a (−201) plane and may be another plane.

The β-Ga₂O₃-based single crystal 25 and the seed crystal 20 are β-Ga₂O₃ single crystals or Ga₂O₃ single crystals doped with an element such as Al or In, and may be, e.g., a (GaₓAl_{y}In_{(1-x-y)})₂O₃ (0<x≦1, 0≦y≦1, 0<x+y≦1) single crystal which is a β-Ga₂O₃ single crystal doped with Al and In. The band gap is widened by adding Al and is narrowed by adding In.

A Sn raw material is added to a β-Ga₂O₃-based raw material so that a desired Sn concentration is obtained. When growing the β-Ga₂O₃-based single crystal 25 to be cut into, e.g., an LED substrate, SnO₂ is added to the β-Ga₂O₃-based raw material so that the Sn concentration is not less than 0.003 mol % and not more than 1.0 mol %. Satisfactory properties as a conductive substrate are not obtained at the concentration of less than 0.003 mol %. On the other hand, problems such as a decrease in the doping effect, an increase in absorption coefficient or a decrease in yield are likely to occur at the concentration of more than 1.0 mol %.

The following is an example of conditions of growing the β-Ga₂O₃-based single crystal 25 in the present embodiment.

The β-Ga₂O₃-based single crystal 25 is grown in, e.g., a nitrogen atmosphere.

In the example shown in FIGS. 1 and 2, the seed crystal 20 having substantially the same horizontal cross-sectional size as the β-Ga₂O₃-based single crystal 25 is used. In this case, a shoulder broadening process for increasing a width of the β-Ga₂O₃-based single crystal 25 is not performed. Therefore, twinning which is likely to occur in the shoulder broadening process can be suppressed.

In this case, the seed crystal 20 is larger than a seed crystal used for typical crystal growth and is susceptible to thermal shock. Therefore, a height of the seed crystal 20 from the die 14 before the contact with the Ga₂O₃-based melt 12 is preferably low to some extent and is, e.g., 10 mm. In addition, a descending speed of the seed crystal 20 until the contact with the Ga₂O₃-based melt 12 is preferably low to some extent and is, e.g., 1 mm/min.

Standby time until pulling up the seed crystal 20 after the contact with the Ga₂O₃-based melt 12 is preferably long to some extent in order to further stabilize the temperature to prevent thermal shock, and is, e.g., 10 min.

A temperature rise rate at the time of melting the raw material in the crucible 13 is preferably low to some extent in order to prevent a rapid increase in temperature around the crucible 13 and resulting thermal shock on the seed crystal 20, and the raw material is melted over, e.g., 11 hours.

(Cutting into β-Ga₂O₃-Based Single Crystal Substrate)

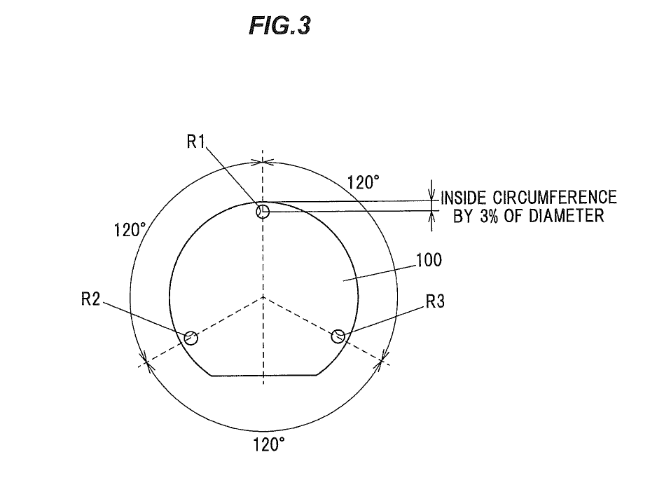

FIG. 3 shows a β-Ga₂O₃-based single crystal substrate 100 formed by cutting the β-Ga₂O₃-based single crystal 25 grown into a plate shape. On the β-Ga₂O₃-based single crystal substrate 100 which has a diameter of 2 inches, three reference points R1, R2 and R3 for forming a three point reference plane used for measuring below-described BOW and WARP are defined inside the circumference by 3% of diameter at 120° degree intervals.

The following is an example of a method of manufacturing the β-Ga₂O₃-based single crystal substrate 100 from the grown β-Ga₂O₃-based single crystal 25.

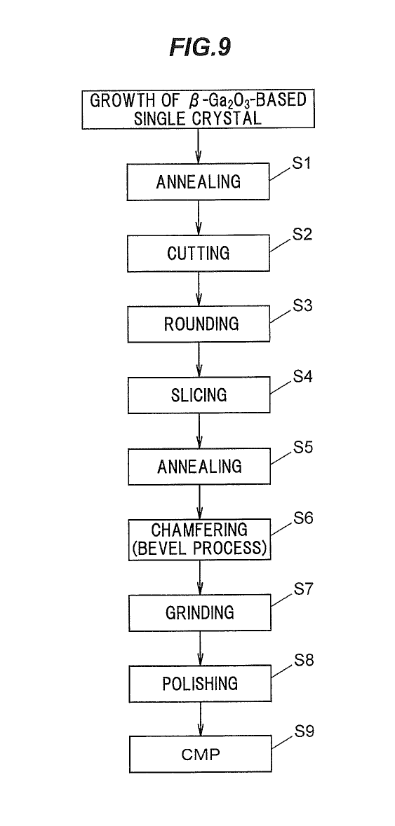

FIG. 9 is a flowchart showing an example of a manufacturing process of a β-Ga₂O₃-based single crystal substrate. The process will be described below with the flowchart.

Firstly, the β-Ga₂O₃-based single crystal 25 having, e.g., an 18 mm-thick plate-shaped portion is grown and is then annealed to relieve thermal stress during single crystal growth and to improve electrical characteristics (Step S1). The atmosphere used is preferably a nitrogen atmosphere but may be another inactive atmosphere such as argon or helium. Annealing temperature is preferably maintained at 1400 to 1600° C. Annealing time at the maintained temperature is preferably about 6 to 10 hours.

Next, the seed crystal 20 and the β-Ga₂O₃-based single crystal 25 are separated by cutting with a diamond blade (Step S2). Firstly, the β-Ga₂O₃-based single crystal 25 is fixed to a carbon stage with heat-melting wax in-between. The β-Ga₂O₃-based single crystal 25 fixed to the carbon stage is set on a cutting machine and is cut for separation. The grit number of the blade is preferably about #200 to #600 (defined by JIS B 4131) and a cutting rate is preferably about 6 to 10 mm per minute. After cutting, the β-Ga₂O₃-based single crystal 25 is detached from the carbon stage by heating.

Next, the edge of the β-Ga₂O₃-based single crystal 25 is shaped into a circular shape by an ultrasonic machining device or a wire-electrical discharge machine (Step S3). An orientation flat(s) can be additionally formed at a desired position(s) of the edge.

Next, the circularly-shaped β-Ga₂O₃-based single crystal 25 is sliced to about 1 mm thick by a multi-wire saw, thereby obtaining the β-Ga₂O₃-based single crystal substrate 100 (Step S4). In this process, it is possible to slice at a desired offset angle. It is preferable to use a fixed-abrasive wire saw. A slicing rate is preferably about 0.125 to 0.3 mm per minute.

Next, the β-Ga₂O₃-based single crystal substrate 100 is annealed to reduce processing strain and to improve electrical characteristics as well as permeability (Step S5). The annealing is performed in an oxygen atmosphere during temperature rise and is performed in a nitrogen atmosphere when maintaining temperature after the temperature rise. The atmosphere used when maintaining the temperature may be another inactive atmosphere such as argon or helium. The temperature to be maintained here is preferably 1400 to 1600° C.

Next, the edge of the β-Ga₂O₃-based single crystal substrate 100 is chamfered (bevel process) at a desired angle (Step S6).

Next, the β-Ga₂O₃-based single crystal substrate is ground to a desired thickness by a diamond abrasive grinding wheel (Step S7). The grit number of the grinding wheel is preferably about #800 to #1000 (defined by JIS B 4131).

Next, the β-Ga₂O₃-based single crystal substrate is polished to a desired thickness using a turntable and diamond slurry (Step S8). It is preferable to use a turntable formed of a metal-based or glass-based material. A grain size of the diamond slurry is preferably about 0.5 μm.

Next, only one side of the β-Ga₂O₃-based single crystal substrate 100 is polished using a polishing cloth and CMP (Chemical Mechanical Polishing) slurry until atomic-scale flatness is obtained (Step S9). The polishing cloth formed of nylon, silk fiber or urethane, etc., is preferable. Slurry of colloidal silica is preferably used. The main surface of the β-Ga₂O₃-based single crystal substrate 100 after the CMP process has a mean roughness of about Ra=0.05 to 1 nm. Meanwhile, a surface opposite to the main surface has an average roughness Ra of not less than 0.1 μm.

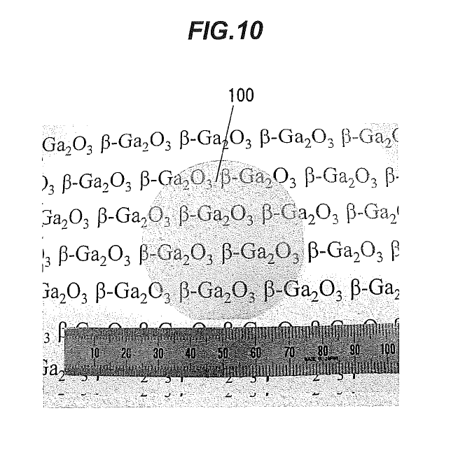

FIG. 10 is a photograph showing the β-Ga₂O₃-based single crystal substrate 100 manufactured from the β-Ga₂O₃-based single crystal 25 through the steps described above. The β-Ga₂O₃-based single crystal substrate 100 does not contain twins and a main surface thereof is excellent in flatness. Therefore, the see-through letters “β-Ga₂O₃” under the β-Ga₂O₃-based single crystal substrate 100 are not broken or distorted.

Since the backside polishing is not performed in the above-mentioned process, the β-Ga₂O₃-based single crystal substrate 100 has a back surface (a surface opposite to the main surface) with an average surface roughness Ra of not less than 0.1 μm, as described above.

Table 1 shows the measurement results of BOW, WARP and TTV of Sample Nos. 1 to 5 of the β-Ga₂O₃-based single crystal substrate 100.

TABLE 1

| Sample No. | BOW | WARP | TTV |
|---|---|---|---|
| 1 | −9.48 | 15.7 | 7.21 |
| 2 | −12.93 | 24.81 | 5.29 |
| 3 | −11.24 | 22.46 | 7.8 |
| 4 | −10.91 | 18.76 | 7.12 |
| 5 | −10.84 | 14.45 | 6.12 |
| Average | −11.1 | 19.21 | 6.7 |
| Standard deviation σ | 1.2 | 4.4 | 1.0 |

The β-Ga₂O₃-based single crystal substrates 100 satisfying −13 μm≦BO≦0, WARP≦25 μm and TTV≦10 μm in Table 1 are preferable.

The measurement results shown in Table 1 and criteria for the measurements will be described below.

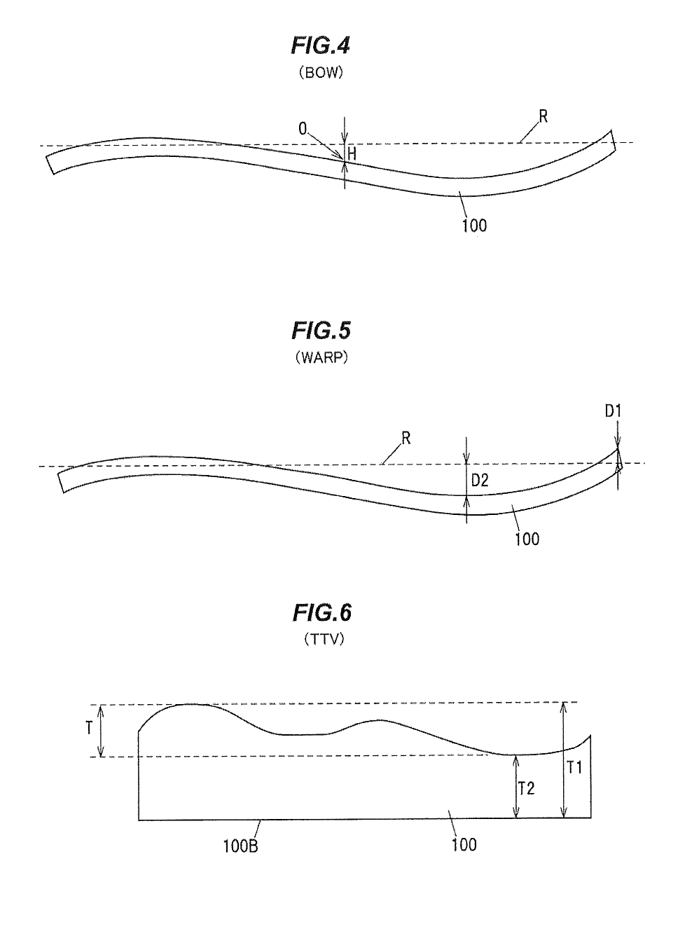

FIG. 4 shows measurement criteria for BOW of the β-Ga₂O₃-based single crystal substrate 100. In FIG. 4, a dotted line R is a three point preference plane defined by a plane passing through the three reference points R1, R2 and R3 on the β-Ga₂O₃-based single crystal substrate 100 shown in FIG. 3 and BOW is a vertical distance H from the center 0 of the substrate 100 to the reference plane R. In FIG. 4, the value of BOW is negative since the center 0 is located below the reference plane R. Meanwhile, the value of BOW is positive when the center 0 of the substrate 100 is located above the reference plane R.

FIG. 5 shows measurement criteria for WARP of the β-Ga₂O₃-based single crystal substrate 100. In FIG. 5, a distance D1 from the three point preference plane R to the highest point of the substrate 100 and a distance D2 from the preference plane R to the lowest point of the substrate 100 are measured, and WARP is determined based on the sum of the absolute values of the measured values. In other words, WARP=|D1|+|D2|.

FIG. 6 shows measurement criteria for TTV of the β-Ga₂O₃-based single crystal substrate 100. In FIG. 6, TTV is a value T which is derived by subtracting T2 from T1 where T1 is a distance between the highest point and a back surface 100B of the β-Ga₂O₃-based single crystal substrate 100 flattened by suction of a vacuum chuck (not shown) and T2 is a distance between the lowest point and the back surface 100B. In other words, TTV=T=|T1−T2|.

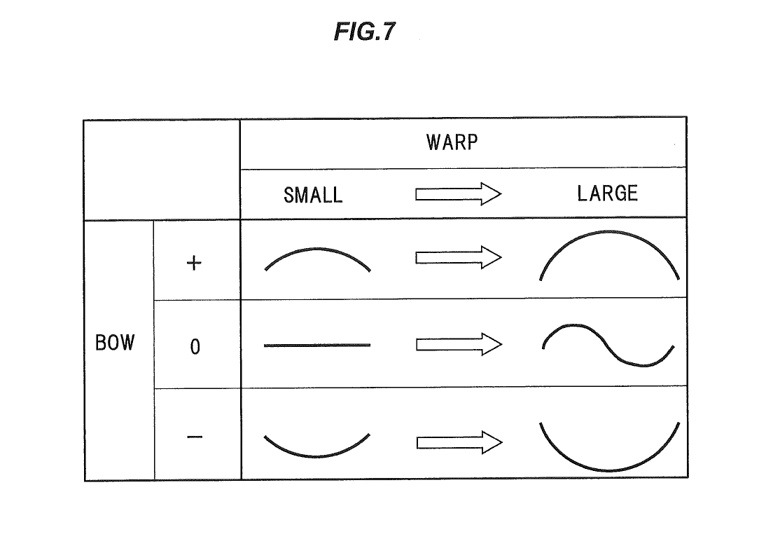

FIG. 7 shows a relation between BOW, WARP and the shapes of substrate indicated by black lines. It is shown that the substrate 100 is curved in a convex shape when BOW is a positive value and, in general, degree of curvature increases with an increase in WARP.

Meanwhile, with BOW=0, the substrate 100 is generally close to flat when WARP is small, and the curve of the substrate 100 is reversed in the opposite direction at the center when WARP is large.

Also, it is shown that the substrate 100 is curved in a concave shape when BOW is a negative value and, in general, degree of curvature increases with an increase in WARP.

The values of BOW, WARP and TTV measured on the samples 1 to 5 are shown in Table 1. BOW, WARP and TTV were measured by a flatness measurement and analysis system (manufactured by Corning Tropel Corporation) using oblique incidence of laser beam.

Crystallinity of the samples 1 to 5 were evaluated by (−402) x-ray diffraction rocking curve measurement.

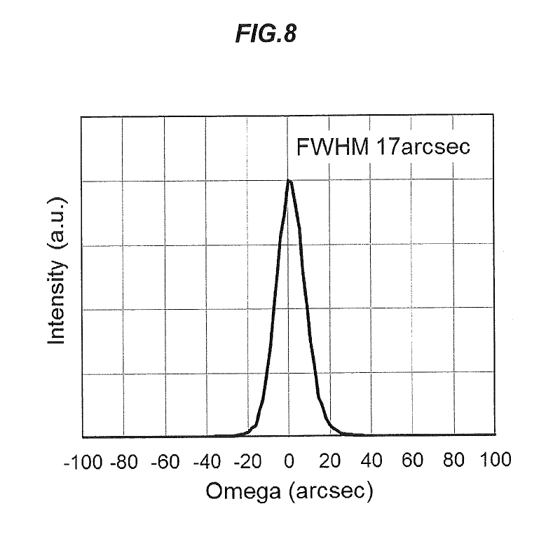

FIG. 8 shows the result of evaluating the crystallinity. Full width at half maximum (FWHM) was 17 seconds and it was evaluated as good.

### Effects of the Embodiment

In the present embodiment, it is possible to grow a β-Ga₂O₃-based single crystal with very good crystallinity in which twins are not contained and cracks and grain boundaries do not occur. This allows slicing, rounding and polishing conditions to be studied and it is thereby possible to provide, for the first time ever, a β-Ga₂O₃-based single crystal substrate with an excellent shape of which BOW, WARP are TTV are not more than predetermined values.

As an example, when growing a plate-shaped β-Ga₂O₃-based single crystal which is doped with Sn and is not less than 65.8 mm in length and 52 mm in width, a 2-inch-diameter conductive substrate with excellent crystal quality can be obtained from a region centered at a point 40 mm from a seed crystal.

The effects of the present embodiment do not depend on the additive concentration and it has been confirmed that variation in the crystal structure of the β-Ga₂O₃-based single crystal in a direction perpendicular to the b-axis direction is substantially the same at least up to 1.0 mol %.

Although the embodiment of the invention has been described, the invention is not intended to be limited to these embodiment, and the various kinds of modifications can be implemented without departing from the gist of the invention.

In addition, the invention according to claims is not to be limited to embodiment. Further, it should be noted that all combinations of the features described in the embodiment are not necessary to solve the problem of the invention.

What is claimed is:

1. A Ga₂O₃-based single crystal substrate, wherein BOW of a main surface is not less than −13 μm and not more than 0 μm.

2. The Ga₂O₃-based single crystal substrate according to claim 1, wherein WARP of the main surface is not more than 25 μm.

3. The Ga₂O₃-based single crystal substrate according to claim 1, wherein TTV of the main surface is not more than 10 μm.

4. The Ga₂O₃-based single crystal substrate according to claim 2, wherein TTV of the main surface is not more than 10 μm.

5. The Ga₂O₃-based single crystal substrate according to claim 1, wherein the main surface has an average roughness Ra of 0.05 nm to 1 nm.

6. The Ga₂O₃-based single crystal substrate according to claim 2, wherein the main surface has an average roughness Ra of 0.05 nm to 1 nm.

7. The Ga₂O₃-based single crystal substrate according to claim 3, wherein the main surface has an average roughness Ra of 0.05 nm to 1 nm.

8. The Ga₂O₃-based single crystal substrate according to claim 4, wherein the main surface has an average roughness Ra of 0.05 nm to 1 nm.

9. The Ga₂O₃-based single crystal substrate according to claim 5, wherein a surface opposite to the main surface has an average roughness Ra of not less than 0.1 μm.

10. The Ga₂O₃-based single crystal substrate according to claim 6, wherein a surface opposite to the main surface has an average roughness Ra of not less than 0.1 μm.

11. The Ga₂O₃-based single crystal substrate according to claim 7, wherein a surface opposite to the main surface has an average roughness Ra of not less than 0.1 μm.

12. The Ga₂O₃-based single crystal substrate according to claim 8, wherein a surface opposite to the main surface has an average roughness Ra of not less than 0.1 μm.

13. The Ga₂O₃-based single crystal substrate according to claim 1, comprising Sn added in an amount of 0.003 to 1.0 mol %.

14. The Ga₂O₃-based single crystal substrate according to claim 2, comprising Sn added in an amount of 0.003 to 1.0 mol %.

15. The Ga₂O₃-based single crystal substrate according to claim 3, comprising Sn added in an amount of 0.003 to 1.0 mol %.

16. The Ga₂O₃-based single crystal substrate according to claim 4, comprising Sn added in an amount of 0.003 to 1.0 mol %.
